(19) United States
(12) Patent Application Publication
(10) Pub. No.: US 2025/0372370 A1
(43) Pub. Date: Dec. 4, 2025

(54) Deposition Process for Dielectric Layer

(71) Applicant: Taiwan Semiconductor Manufacturing Company, Ltd., Hsin-Chu (TW)

(72) Inventors: Chang-Ta CHEN, New Taipei City (TW); Ming-Chang WEN, Kaohsiung City (TW); Kuo-Feng YU, Hsinchu County (TW); Zhen-Cheng WU, Hsinchu County (TW); Yen-Chun HUANG, Taipei City (TW); Sen-Hong SYUE, Hsinchu (TW); Yun Chen TENG, New Taipei City (TW); Yoh-Rong LIU, Taipei City (TW); Che-Hao CHANG, Hsinchu City (TW); Keng-Yao CHEN, Hsinchu (TW); Yun LEE, Taipei County (TW); Chung-Yu LIN, Kaohsiung City (TW)

(21) Appl. No.: 19/016,451

(22) Filed: Jan. 10, 2025

Related U.S. Application Data
(60) Provisional application No. 63/655,401, filed on Jun. 3, 2024.

(51) Int. Cl. H01L 21/02; H10D 30/00; H10D 30/01; H10D 30/43; H10D 62/10; H10D 62/13; H10D 62/83; H10D 64/01; H10D 84/01; H10D 84/83

(52) U.S. Cl. CPC H01L 21/02348; H01L 21/02271; H01L 21/02274; H10D 30/014; H10D 30/019; H10D 62/83; H10D 64/017; H10D 84/0144; H10D 30/43; H10D 30/501; H10D 62/121; H10D 62/151; H10D 84/832

(57) ABSTRACT

An exemplary flowable chemical vapor deposition method includes depositing a flowable dielectric material over a substrate, ultraviolet curing the flowable dielectric material, and annealing the ultraviolet cured, flowable dielectric material. The flowable dielectric material fills a space between a first gate structure and a second gate structure. An ultraviolet power of the ultraviolet curing is greater than about 80%, and an annealing temperature of the annealing is less than about 500° C. A thickness of the flowable dielectric material deposited over tops of the first gate structure and the second gate structure is less than about 200 nm. The ultraviolet power, the temperature, and an as-deposited thickness may be selected based on germanium pile up characteristics expected at an inner spacer/source/drain interface.

This is a non-provisional application of and claims benefit of U.S. Provisional Patent Application Ser. No. 63/655,401, filed Jun. 3, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component that can be created using a fabrication process) has decreased. This scaling down process generally provides benefits by increasing production efficiency and lowering associated costs. Such scaling down has also increased the complexity of processing and manufacturing ICs, and for these advances to be realized, similar developments in IC materials and manufacturing are needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for forming a dielectric structure over a device according to various aspects of the present disclosure.

FIG. 2 is a top view of a device, in portion or entirety, that may be processed to form a dielectric structure thereover, according to various aspects of the present disclosure.

FIGS. 3A-10A are diagrammatic cross-sectional views of the device, in portion or entirety, of FIG. 2 along line A-A at various stages of fabrication (such as those associated with the method of FIG. 1) according to various aspects of the present disclosure.

FIGS. 3B-10B are diagrammatic cross-sectional views of the device, in portion or entirety, of FIG. 2 along line B-B at various stages of fabrication (such as those associated with the method of FIG. 1) according to various aspects of the present disclosure.

FIG. 8C is a diagrammatic cross-sectional view of the device, in portion or entirety, of FIG. 2 along line C-C at the stage of fabrication associated with FIG. 8A and FIG. 8B, according to various aspects of the present disclosure.

FIG. 11 depicts germanium depth profiles of interface regions of inner spacers and source/drains after forming interlayer dielectric layers by flowable chemical vapor deposition processes using different annealing temperatures, including by that associated with the method of FIG. 1, according to various aspects of the present disclosure.

FIG. 12 is a plot comparing dielectric structures, such as interlayer dielectric layers, formed by different flowable chemical vapor deposition processes, including by that associated with the method of FIG. 1, according to various aspects of the present disclosure.

FIG. 13 is a flow chart of a method, in portion or entirety, that may be implemented by the method of FIG. 1, according to various aspects of the present disclosure.

### DETAILED DESCRIPTION

The present disclosure provides flowable chemical vapor deposition (FCVD) techniques for high aspect ratio gap filling applications, such as FCVD techniques for forming high quality interlayer dielectric layers in high aspect ratio gaps between gates of multigate transistors, such as fin-like field effect transistors (FinFETs), gate-all-around (GAA) transistors (e.g., nanowire transistors or nanosheet transistors), fork-sheet transistors, or the like.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for case of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

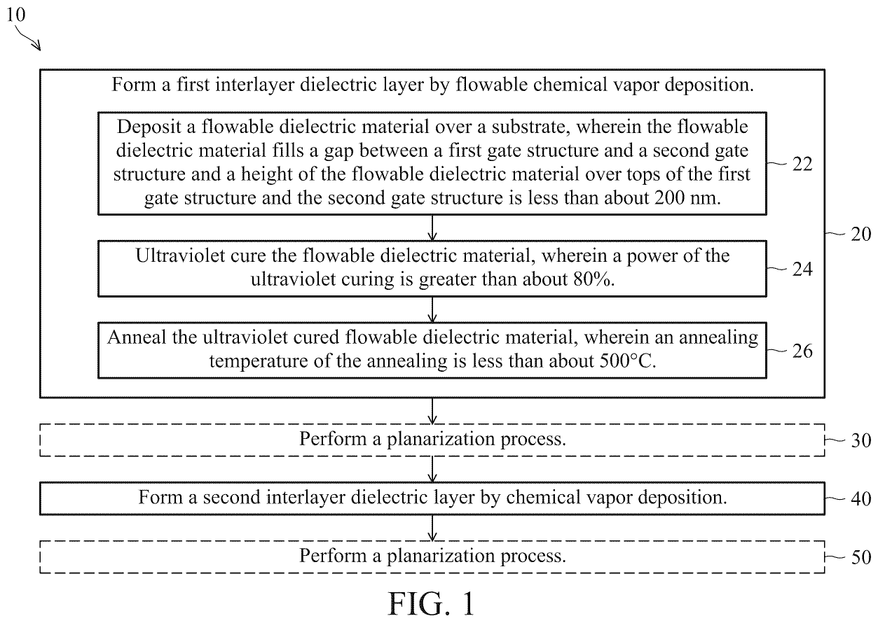

FIG. 1 is a flow chart of a method 10, in portion or entirety, for forming a dielectric structure over a device, according to various aspects of the present disclosure. The dielectric structure may include more than one interlayer dielectric (ILD) layer. At block 15, method 10 includes forming a first ILD layer by flowable chemical vapor deposition. The flowable chemical vapor deposition includes depositing a flowable dielectric material over a substrate at block 22, ultraviolet curing the flowable dielectric material at block 24, and annealing the ultraviolet cured flowable dielectric material at block 26. The flowable dielectric material may fill high aspect ratio gaps, such as a gap between a first gate structure and a second gate structure. Parameters of the flowable chemical vapor deposition are configured to optimize quality of the first ILD layer while optimizing wafer acceptance testing performance, such as described herein. For example, deposition of the flowable dielectric material is tuned to provide a thin layer of the flowable dielectric material over tops of the first gate structure and the second gate structure at block 22 (e.g., a height of the flowable dielectric material over the tops of the first gate structure and the second gate structure is less than about 200 nm), the ultraviolet curing exposes the flowable dielectric material to ultraviolet radiation having an ultraviolet power/intensity greater than 805, and the annealing process is a low temperature annealing process (e.g., an anneal temperature is less than about 500° C.). At block 30, a planarization process may be performed, for example, on the first ILD layer. The planarization process may be a chemical mechanical polishing process. The planarization process may remove portions of the first ILD layer that are disposed over tops of the first gate structure and the second gate structure. In some embodiments, a first contact etch stop layer (CESL) may be formed before the first ILD layer. In such embodiments, the first CESL partially fills the gap, the first ILD layer fills a remainder of the gap, and a composition of the first CESL is different than a composition of the first ILD layer to enable etch selectivity therebetween.

At block 40, method 10 includes forming a second ILD layer, for example, by chemical vapor deposition. Because the second ILD layer may not be formed in gaps between device features and/or may be performed in small aspect ratio gaps, the second ILD layer may be formed by a different type of deposition process than the first ILD layer, such as a different type of chemical vapor deposition. For example, the second ILD layer may be formed by a plasma enhanced chemical vapor deposition, instead of flowable chemical vapor deposition. In such example, the second ILD layer may be a plasma enhanced oxide layer. In some embodiments, dummy gates of the first gate structure and the second gate structure are replaced with gate stacks before forming the second ILD layer. In some embodiments, a second CESL may be formed before the second ILD layer. In such embodiments, a composition of the second CESL is different than a composition of the second ILD layer to enable etch selectivity therebetween. At block 50, a planarization process may be performed, for example, on the second ILD layer. The planarization process may be a chemical mechanical polishing process. In some embodiments, the dielectric structure may be formed over a source/drain, and a source/drain contact structure may be formed in the second ILD layer, in the first ILD layer, and on the source/drain. Additional steps may be provided before, during, and after method 10, and some of the steps described may be moved, replaced, or eliminated for additional embodiments of method 10. The discussion that follows illustrates devices that may be fabricated to include a dielectric structure (e.g., an ILD layer), such as that fabricated according to method 10. From the description herein, it may be seen that dielectric structures, such as ILD layers, fabricated according to the methods described in the present disclosure offer advantages over dielectric structures fabricated according to other methods. It is understood, however, that different embodiments may have different advantages, and no particular advantage is required of any embodiment.

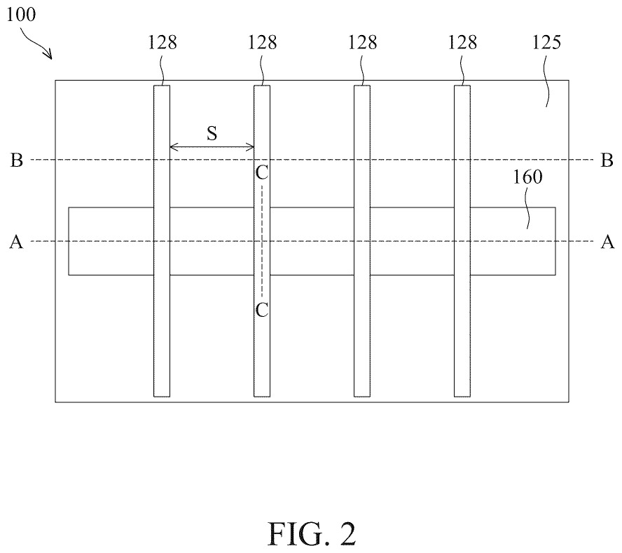

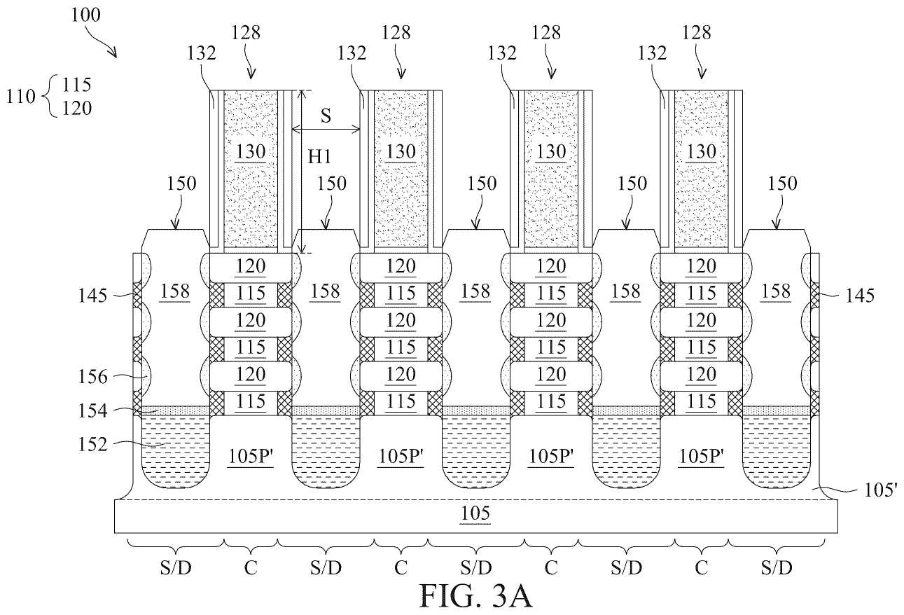

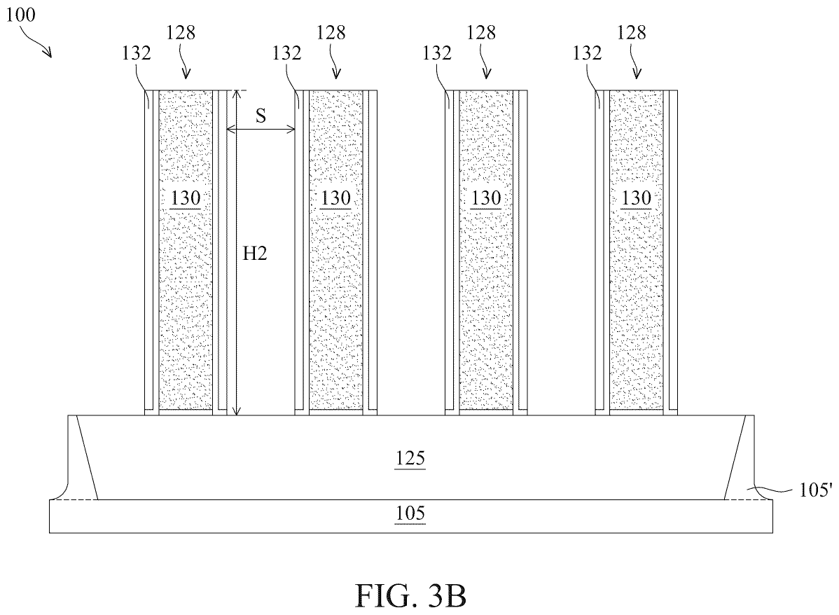

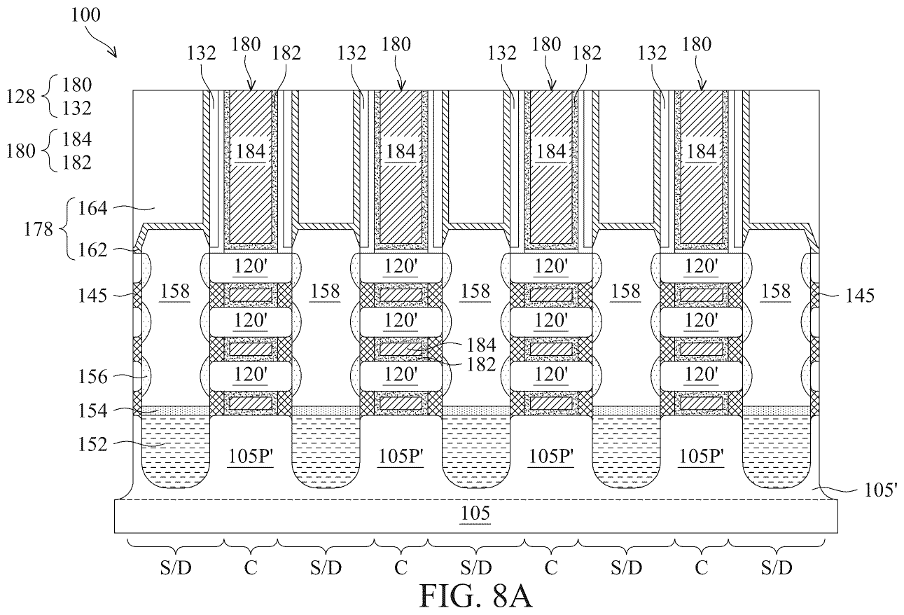

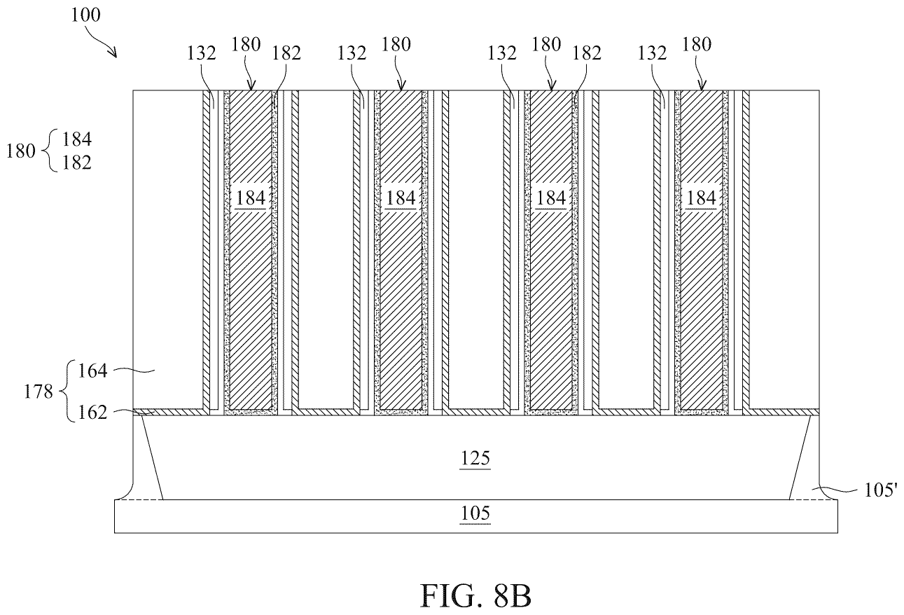

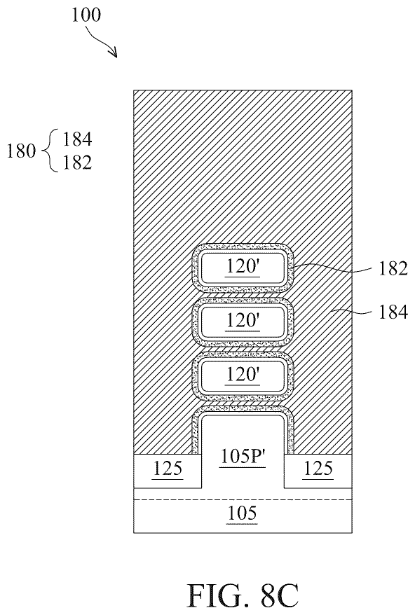

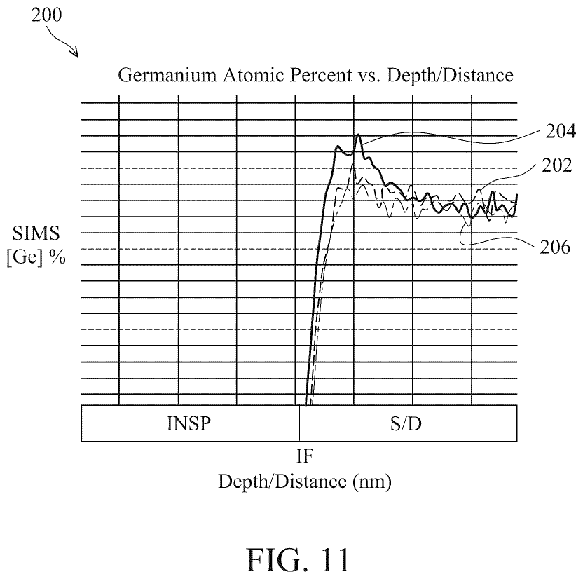

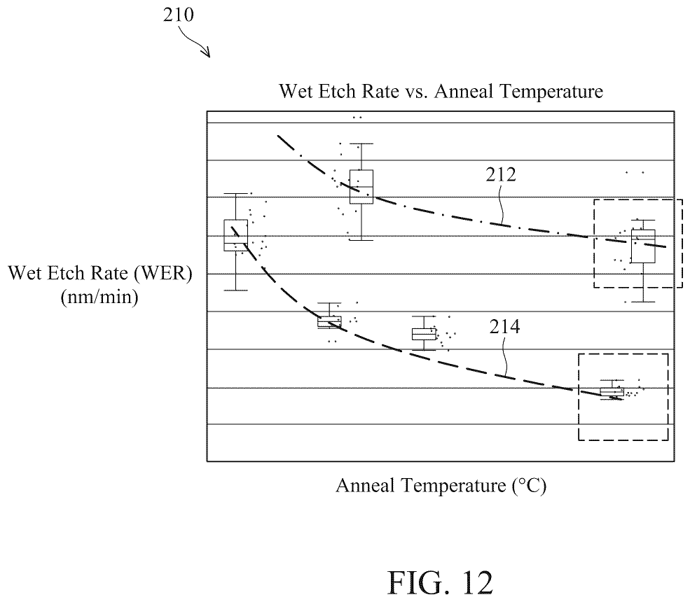

FIG. 2 is a top view of a device 100, in portion or entirety, that may be processed to form a dielectric structure thereover, such as that formed by method 10 of FIG. 1, according to various aspects of the present disclosure. FIGS. 3A-10A are diagrammatic cross-sectional views of device 100, in portion or entirety, along line A-A of FIG. 2 at various stages of fabrication (such as those associated with method 10 of FIG. 1) according to various aspects of the present disclosure. FIGS. 3B-10B are diagrammatic cross-sectional views of device 100, in portion or entirety, along line B-B of FIG. 2 at various stages of fabrication (such as those associated with method 10 of FIG. 1) according to various aspects of the present disclosure. FIG. 8C is a cross-sectional view of device 100, in portion or entirety, along line C-C of FIG. 2 at the stage of fabrication of FIG. 8A and FIG. 8B, according to various aspects of the present disclosure. FIG. 11 and FIG. 12 provide data and/or results associated with dielectric structures that may be fabricated according to flowable chemical vapor deposition processes, such as the dielectric structure fabricated over device 100 and/or the dielectric structure fabricated by method 10 of FIG. 1, according to various aspects of the present disclosure. FIG. 2, FIGS. 3A-10A, FIGS. 3B-10B, FIG. 8B, FIG. 11, and FIG. 12 are discussed concurrently herein for ease of description and understanding. FIG. 2, FIGS. 3A-10A, FIGS. 3B-10B, FIG. 8B, FIG. 11, and FIG. 12 have been simplified for the sake of clarity to better understand the inventive concepts of the present disclosure. Additional features may be added in device 100, and some of the features described below may be replaced, modified, or eliminated in other embodiments of device 100.

Device 100 may include at least one transistor, such as a gate-all-around (GAA) transistor (i.e., a transistor having a gate that at least partially surrounds a suspended channel(s) (for example, a nanowire(s), a nanosheet(s), a nanobar(s), or the like) that extends between source/drains). Device 100 may be included in a microprocessor, a memory, other integrated circuit (IC) device, or combinations thereof. In some embodiments, device 100 is a portion of an IC chip, a system on chip (SoC), or portion thereof, and device 100 may include various passive electronic devices and/or active electronic devices, such as resistors, capacitors, inductors, diodes, p-type field effect transistors (PFETs), n-type FETs (NFETs), metal-oxide-semiconductor FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof.

Referring to FIG. 2, FIG. 3A, and FIG. 3B, a device precursor of device 100 may be formed and/or received, which is then processed as described herein. Device 100 may include a substrate 105, a mesa 105′, a multilayer stack 110 (including, e.g., mesas 105P′, sacrificial layers 115, and semiconductor layers 120), substrate isolation structures 125, and gate structures 128. Each gate structure 128 may include a respective dummy gate stack 130 and respective gate spacers 132. Device 100 may further include inner spacers 145 and source/drain structures 150. Each source/drain structure 150 may be multilayered, including, for example, a semiconductor layer 152, an insulator layer 154, a semiconductor layer 156, and a semiconductor layer 158. An active region 160 of device 100 extends lengthwise along an x-direction (i.e., length is along the x-direction, width is along a y-direction, and height is along a z-direction), and active region 160 may be oriented substantially parallel to another active regions. Active region 160 may include channel regions (C), source regions, and drain regions, and source regions and drain regions are collectively referred to as source/drain regions (S/D). In the depicted embodiment, device 100 is processed to include GAA transistors, and active region 160 is a GAA-based active region. In such embodiments, active region 160 may have source/drain regions formed by source/drain structures 150 and channel regions formed by semiconductor layers 120.

Substrate 105, mesa 105′, and mesas 105P′ include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 105 is a silicon substrate. In some embodiments, substrate 105 is a semiconductor-on-insulator substrate, such as a silicon-on-insulator (SOI) substrate, a silicon germanium-on-insulator (SGOI) substrate, or a germanium-on-insulator (GOI) substrate. Substrate 105 (and mesa 105′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include p-type dopants and n-type dopants. The doped regions may provide a p-well structure, an n-well structure, a dual-well structure, a raised structure, other suitable structure, or combinations thereof. In some embodiments, substrate 105 and/or mesa 105′, and semiconductor layers thereover, may include an n-well and/or a p-well. For example, substrate 105 and/or mesa 105′ may include a p-well in an n-type transistor region and an n-well in a p-type transistor region.

Sacrificial layers 115 and semiconductor layers 120 are stacked vertically (e.g., along the z-direction) in an interleaving and/or alternating configuration from a top of substrate 105. A composition of sacrificial layers 115 is different than a composition of semiconductor layers 120 to achieve etch selectivity. For example, sacrificial layers 115 and semiconductor layers 120 include different materials, constituent atomic percentages, constituent weight percentages, other characteristics, or combinations thereof to achieve etch selectivity. In some embodiments, sacrificial layers 115 include silicon germanium, semiconductor layers 120 include silicon, and an etch rate of semiconductor layers 120 is different than an etch rate of sacrificial layers 115 to a given etchant. In some embodiments, sacrificial layers 115 and semiconductor layers 120 include the same material but with different constituent atomic percentages. For example, sacrificial layers 115 and semiconductor layers 120 may include silicon germanium but with different germanium atomic percentages. In some embodiments, sacrificial layers 115 are dielectric layers (e.g., sacrificial layers 115 may be oxide layers) and semiconductor layers 120 are silicon layers to provide etch selectivity. Sacrificial layers 115 and semiconductor layers 120 may include any combination of materials that provides desired etching selectivity, desired oxidation rate differences, desired performance characteristics, or combinations thereof (e.g., materials that maximize current flow), including any of the materials disclosed herein.

Semiconductor layers 120 or portions thereof may form channels of transistors of device 100. In FIG. 3A, multilayer stack 110 includes three sacrificial layers 115 and three semiconductor layers 120. Multilayer stack 110 thus includes three semiconductor layer pairs disposed over substrate 105, each of which has a respective sacrificial layer 115 and a respective semiconductor layer 120. After processing of multilayer stack 110, this configuration may result in transistors having three channels. However, in some embodiments, multilayer stack 110 includes different numbers of semiconductor layers 120 depending, for example, on a number of channels desired for transistors of and/or design requirements of device 100. For example, multilayer stack 110 may include two to six semiconductor layer pairs, each of which may have a respective sacrificial layer 115 and a respective semiconductor layer 120.

Substrate isolation structures 125 may be formed adjacent to and around a lower portion of multilayer stack 110 (e.g., mesas 105P′ thereof), and active region 160 may be separated from other active regions and/or device regions by substrate isolation structures 125. Substrate isolation structures 125 may electrically isolate active region 160 (e.g., mesas 105P′ and/or source/drain structures 150 thereof) from other active regions and/or device regions. Substrate isolation structures 125 include silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 125 may have a multilayer structure. For example, substrate isolation structures 125 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 125 may include a bulk dielectric over a doped liner, such as a boron silicate glass (BSG) liner and/or a phosphosilicate glass (PSG) liner. Dimensions and/or characteristics of substrate isolation structures 125 may be configured to provide shallow trench isolation (STI) structures, deep trench isolation (DTI) structures, local oxidation of silicon (LOCOS) structures, other suitable isolation structures, or combinations thereof.

Gate structures 128 are formed over channel regions (C) of active region 160 (e.g., multilayer stack 110) and between respective source/drain regions (S/D) of active region 160 (e.g., source/drain structures 150). As noted, gate structures 128 may include a respective dummy gate stack 130 and respective gate spacers 132. Gate structures 128 (also referred to as gate lines) extend lengthwise along a direction different than (e.g., orthogonal to) the lengthwise direction of active region 160, such that gate structures 128 are disposed over the channel regions of active region 160 and substrate isolation structures 125. For example, gate structures 128 extend along the y-direction, having a length along the y-direction, a width along the x-direction, and a height along the z-direction. Gate structures 128 may extend substantially parallel to one another, such as depicted, and gate structures 128 have a spacing S therebetween. In FIG. 3A (e.g., the X-Z plane), gate structures 128 are disposed on tops of respective channel regions of active region 160 (e.g., multilayer stack 110), gate structures 128 are disposed between respective source/drain regions of active region 160 (e.g., source/drain structures 150), and gate structures 128 have a height H1. In FIG. 3B (e.g., the X-Z plane), gate structures 128 are disposed over tops of substrate isolation structures 125, and gate structures 128 have a height H2. Height H2 is greater than height H1. In another cross-sectional view (e.g., a Y-Z plane), gate structures 128 may wrap respective channel regions of active region 160.

In FIG. 3A and FIG. 3B, gate structures 128 are separated by a spacing S, gate structures 128 have a height H1 over an active region (e.g., over channel regions of active region 160), and gate structures 128 have a height H2 over an isolation region (e.g., over substrate isolation structures 125). An aspect ratio of gaps between gate patterns (e.g., gate structures 128) in active region 160 is thus given by a ratio of height H1 to spacing S, and an aspect ratio of the gaps between the gate patterns in the isolation region is thus given by a ratio of height H2 to spacing S. Height H2 is greater than height H1, such that the aspect ratio of the gaps between gate structures 128 in the isolation region is greater than the aspect ratio of the gaps between gate structures 128 in active region 160. In some embodiments, the aspect ratio of the gaps between gate structures 128 in the isolation region is greater than about 10 (e.g., a ratio of height H2 to spacing S is at least 10:1). In some embodiments, the aspect ratio of the gaps between gate structures 128 in the active region is greater than about 2.

Dummy gate stacks 130 may include a dummy gate dielectric and a dummy gate electrode. The dummy gate dielectric includes a dielectric material, such as silicon oxide and/or other suitable dielectric material. The dummy gate electrode includes a suitable dummy gate material, such as polysilicon. Dummy gate stacks 130 may further include a hard mask, which may be configured to protect the dummy gate dielectric and/or the dummy gate electrode during processing. For example, the hard mask may include a material that is resistant to an etching process, such as etching associated with forming source/drain recesses and/or etching associated with forming source/drain contact openings, to protect the dummy gate dielectric and/or the dummy gate electrode therefrom. In some embodiments, the hard mask has a multilayer structure. The hard mask includes any suitable hard mask material.

Gate spacers 132 are formed adjacent to and along sidewalls of dummy gate stacks 130. Gate spacers 132 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 132 have a multilayer structure, such as two or more dielectric layers having different compositions. In some embodiments, gate spacers 132 include more than one set of spacers, such as seal spacers, offset spacers, sacrificial spacers, dummy spacers, main spacers, or combinations thereof. In such embodiments, the various sets of spacers may have different compositions.

Inner spacers 145 are disposed under gate structures 128 (e.g., under gate spacers 132 thereof) and along sidewalls of sacrificial layers 115. Inner spacers 145 are disposed between sacrificial layers 115 and source/drain structures 150, between adjacent semiconductor layers 120, and between bottommost semiconductor layer 120 and mesas 105P′. Inner spacers 145 include a dielectric material that includes silicon, oxygen, carbon, nitrogen, or combinations thereof, such as silicon oxide, silicon nitride, silicon oxynitride, silicon carbide, silicon oxycarbonitride, etc. In some embodiments, inner spacers 145 include a low-k dielectric material. In some embodiments, dopants (e.g., p-type and/or n-type) are introduced into the dielectric material, and inner spacers 145 include doped dielectric material(s).

Source/drain structures 150 include a semiconductor material, source/drain structures 150 may be doped with n-type dopants and/or p-type dopants, and source/drain structures 150 may have the same or different compositions and/or materials. In some embodiments, the semiconductor material(s) of source/drain structures 150 are formed by an epitaxy process, and source/drain structures 150 are formed of epitaxially grown/deposited semiconductor material. In such embodiments, source/drain structures 150 may be referred to as epitaxial source/drains. In some embodiments (e.g., when forming portions of n-type transistors), source/drain structures 150 may include silicon doped with carbon, phosphorous, arsenic, other n-type dopant, or combinations thereof. In some embodiments (e.g., when forming portions of p-type transistors), source/drain structures 150 may include silicon germanium or germanium doped with boron, other p-type dopant, or combinations thereof. In some embodiments, doped regions, such as heavily doped source/drain (HDD) regions, lightly doped source/drain (LDD) regions, other doped regions, or combinations thereof, are disposed in source/drain structures 150. In some embodiments, the doped regions, such as LDD regions, may extend into channel regions. As used herein, source/drain region, source/drain, source/drain structure, epitaxial source/drain, epitaxial source/drain feature, etc. may refer to a source of device 100, a drain of device 100, or a source and/or a drain of multiple devices (including device 100).

Each source/drain structure 150 may include a respective semiconductor layer 152, a respective insulator layer 154, a respective semiconductor layer 156, and a respective semiconductor layer 158. Semiconductor layers 152 are disposed on mesas 105P′ and/or substrate 105. In the depicted embodiment, semiconductor layers 152 include dopant-free semiconductor material (i.e., substantially free of n-type and p-type dopants). For example, no intentional doping is performed when forming semiconductor layers 152, e.g., by an epitaxial growth process. Semiconductor layers 152 may thus provide high resistance paths at bottoms of source/drain structures 150, thereby hindering leakage current from flowing between source/drain structures 150 through mesas 105P′ and/or substrate 105. In some embodiments, the undoped semiconductor layers are formed of include silicon, germanium, silicon germanium, other suitable semiconductor materials, or combinations thereof. For example, semiconductor layers 152 may be dopant-free silicon or dopant-free silicon germanium layers.

Insulator layers 154 are disposed on semiconductor layers 152, and insulator layers 154 may be disposed between semiconductor layers 158 and semiconductor layers 152. Insulator layers 154 include an electrically insulating material, such as a dielectric material, that may also hinder unwanted leakage current from flowing between source/drain structures 150 (e.g., semiconductor layers 158 thereof) through mesas 105P′ and/or substrate 105. In some embodiments, insulator layers 154 include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. In some embodiments, insulator layers 154 include a metal-comprising dielectric material, such as a metal oxide material (e.g., aluminum oxide and/or hafnium oxide) and/or a metal nitride material. In some embodiments, insulator layers 154 include a doped semiconductor material that includes an opposite type of dopant than semiconductor layers 158. For example, where source/drain structures 150 are portions of p-type transistors having p-type doped semiconductor layers, insulator layers 154 may include an n-type doped semiconductor material, such as phosphorous-doped silicon. In another example, where source/drain structures 150 are portions of n-type transistors having n-type doped semiconductor layers, insulator layers 154 may include p-doped semiconductor material, such as boron-doped silicon.

Semiconductor layers 156 and semiconductor layers 158 are disposed over insulator layers 154 and are coupled to semiconductor layers 120. Semiconductor layers 156 may be disposed between semiconductor layers 158 and semiconductor layers 120. In the depicted embodiment, semiconductor layers 156 and semiconductor layers 158 include a semiconductor material (e.g., silicon, germanium, silicon germanium, other suitable semiconductor materials, or combinations thereof) that is doped with n-type dopants and/or p-type dopants. Semiconductor layers 156 and semiconductor layers 158 may have different compositions and/or different dimensions/configurations, and the different compositions may be achieved with different semiconductor materials, different dopants, different constituent atomic percentages, different dopant concentrations, or combinations thereof. For example, semiconductor layers 158 may be heavily doped semiconductor layers, and semiconductor layers 156 may be lightly doped semiconductor layers, where a dopant concentration of the heavily doped semiconductor layers is greater than a dopant concentration of the lightly doped semiconductor layers. In some embodiments, semiconductor layers 156 and semiconductor layers 158 may include silicon doped with different concentrations of carbon, phosphorous, arsenic, antimony, other n-type dopant, or combinations thereof. In another example, semiconductor layers 156 and semiconductor layers 158 may include silicon germanium doped with different concentrations of boron, gallium, other p-type dopant, or combinations thereof. In some embodiments, semiconductor layers 156 and semiconductor layers 158 include materials and/or dopants that provide desired tensile stress and/or compressive stress in the channel regions.

Before forming source/drain structures 150, multilayer stack 110 (e.g., mesa 105′, sacrificial layers 115, and semiconductor layers 120 thereof) may extend continuously and substantially along an x-direction, having a length along the x-direction, a width along the y-direction, and a height along the z-direction. Multilayer stack 110 may be referred to as a fin, a fin structure, a fin element, an active fin region, an active region, etc. In some embodiments, mesa 105′ is a patterned, projecting portion and/or extension of substrate 105, and mesa 105′ may be referred to as a substrate extension, a substrate fin portion, a fin portion, an etched substrate portion, etc. While forming source/drain structures 150, sacrificial layers 115, semiconductor layers 120, and mesa 105′ may be removed to form source/drain recesses in source/drain regions of active region 160, in which source/drain structures 150 are formed. After forming the source/drain recesses, which may extend into mesa 105′, portions of multilayer stack 110 may remain in the channel regions of active region 160, and such portions may include mesas 105P′, sacrificial layers 115, and semiconductor layers 120, such as depicted.

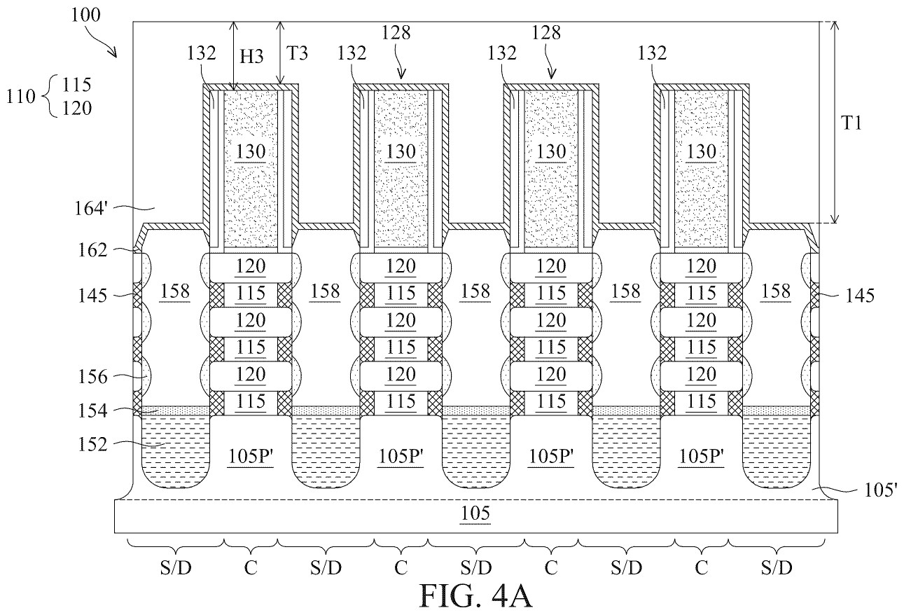

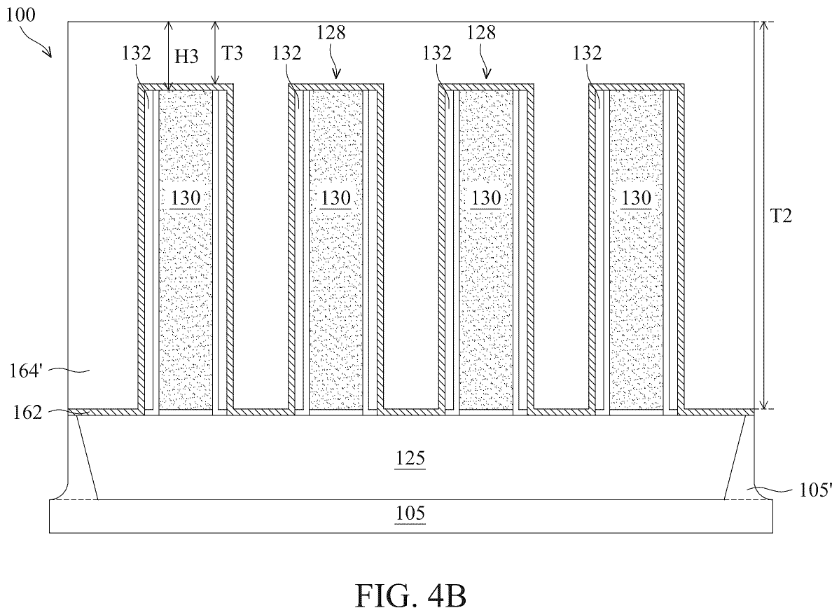

Referring to FIG. 4A and FIG. 4B, a contact etch stop layer (CESL) 162 may be formed over device 100, such as on gate structures 128, source/drain structures 150, substrate isolation structures 125, and substrate 105 (e.g., mesa 105′ thereof). CESL 162 partially fills the gaps/spacing S between gate structures 128. A composition of CESL 162 is different than a composition of a subsequently formed interlayer dielectric (ILD) layer to enable etching selectivity therebetween. In some embodiments, CESL 162 includes a silicon-comprising dielectric material. For example, CESL 162 includes silicon and nitrogen and/or carbon, such as silicon nitride, silicon carbide, silicon oxynitride, silicon oxycarbonitride, silicon carbonitride, silicon oxycarbide, other silicon-comprising dielectric material (which may include silicon and nitrogen, carbon, oxygen, other suitable dielectric constituent, or combinations thereof), or combinations thereof. In some embodiments, CESL 162 includes a metal-comprising dielectric material. For example, CESL 162 includes metal and oxygen, nitrogen, carbon, or combinations thereof, such as a metal oxide (e.g., aluminum oxide) and/or a metal nitride (e.g., aluminum nitride). The metal may be aluminum, hafnium, titanium, copper, manganese, vanadium, other suitable metal, or combinations thereof. In some embodiments, CESL 162 has a multilayer structure. CESL 162 may be formed by chemical vapor deposition (CVD), atomic layer deposition (ALD), other suitable deposition process, or combinations thereof.

Referring to FIGS. 4A-6A and FIGS. 4B-6B, an interlayer dielectric (ILD) layer 164 is formed over device 100, such as on CESL 162. ILD layer 164 fills remainders of the gaps/spacing S between gate structures 128. ILD layer 164 includes a silicon-and-oxygen-comprising dielectric material. For example, ILD layer 164 is a silicon oxide layer. In some embodiments, the silicon-and-oxygen-comprising dielectric material is a low-k dielectric material, which generally refers to a dielectric material having a dielectric constant less than a dielectric constant of silicon dioxide (k≈3.9). For example, ILD layer 164 may be a porous silicon oxide layer, which may have a dielectric constant less than about 2.5 (k≈2.5). In another example, ILD layer 164 may be a carbon-doped silicon oxide layer (e.g., an SiOC layer), which may have a dielectric constant less than about 2.5 (k≈2.5). In some embodiments, ILD layer 164 is a doped silicon oxide layer, such as a carbon-doped silicon oxide layer, a phosphorous-doped silicon oxide layer (e.g., PSG), a boron-doped silicon oxide layer (e.g., BSG), a boron-and-phosphorous-doped silicon oxide layer (e.g., BPSG), a fluorine-doped silicon oxide layer (e.g., FSG), other suitably doped silicon oxide layer, or combinations thereof. In some embodiments, ILD layer 164 is a tetraethylorthosilicate (TEOS)-formed oxide layer. In some embodiments, ILD layer 164 is a benzocyclobutene (BCB)-based dielectric layer.

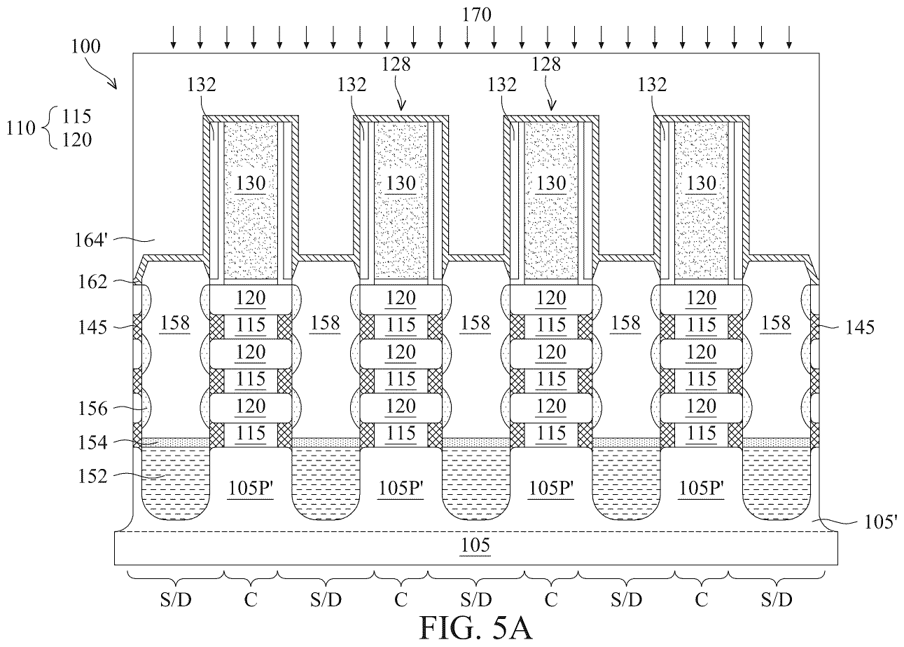

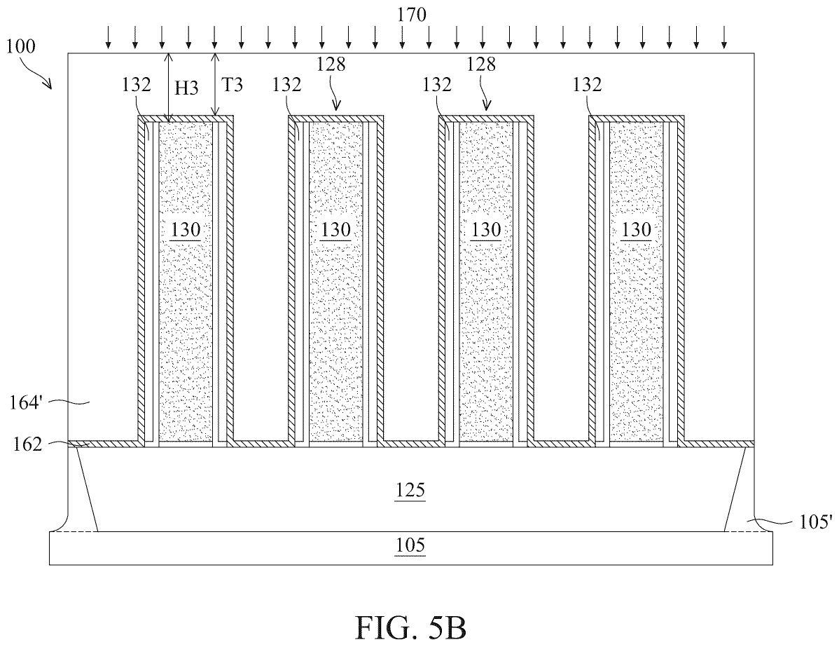

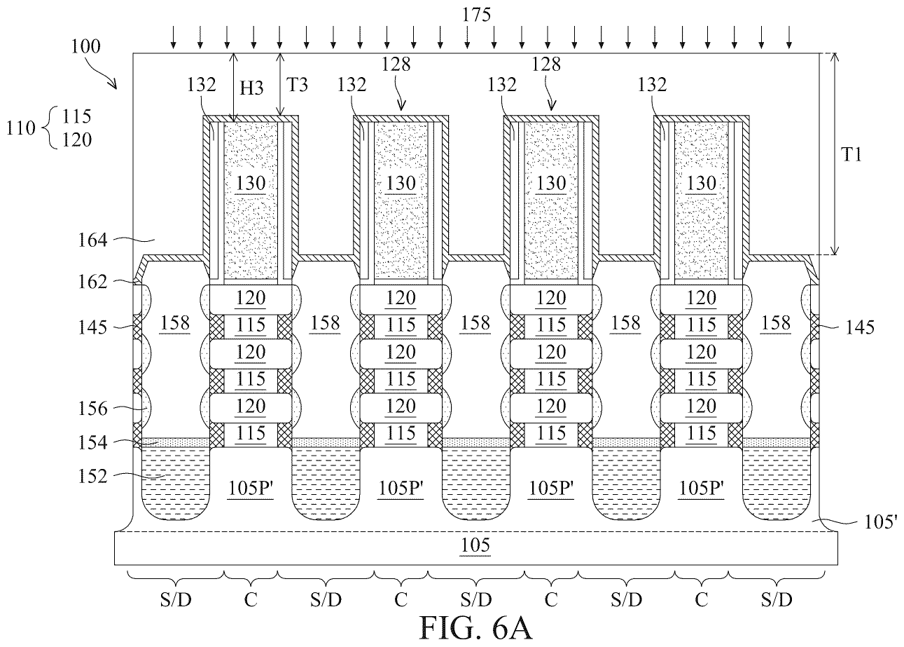

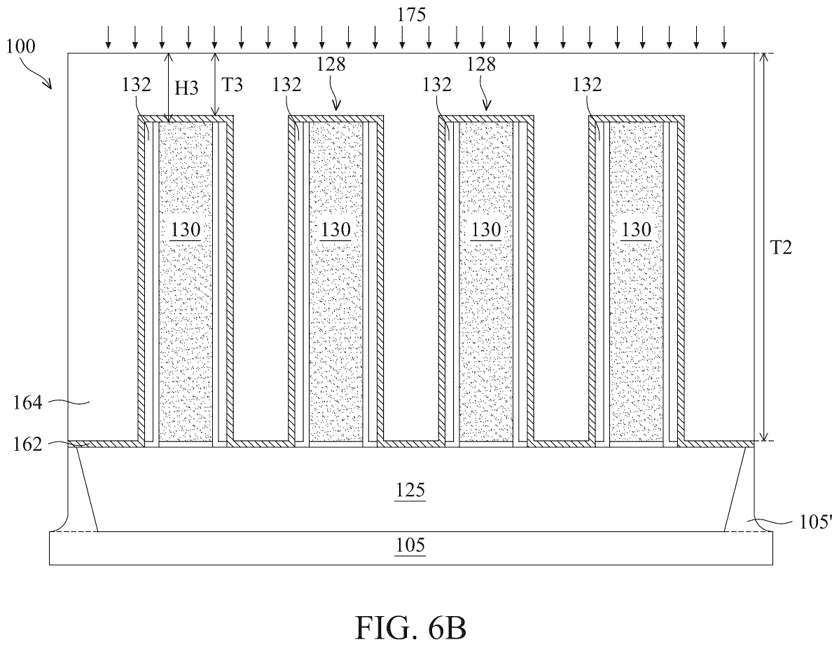

Stacking channels has been observed to increase device density and improve device performance. For example, configuring transistors with stacked semiconductor layers 120 reduces an area consumed by the transistors, such that more transistors may fit into a given area, while also boosting drive current of the transistors. However, as heights of device features (e.g., gates) increase to accommodate stacked channel configurations and spacings between the device features remain small (or decrease) to accommodate the higher device densities of scaled integrated circuit technology nodes, aspect ratios of gaps between the device features have presented gap fill challenges. For example, voids/seams are more likely to form in an insulating material (e.g., ILD layer 164) that fills high aspect ratio gaps, such as the high aspect ratio gaps between gate structures 128 of device 100. Accordingly, referring to FIGS. 4A-6A and FIGS. 4B-6B, to optimize filling of the high aspect ratio gaps between gate structures 128 (e.g., by reducing and/or eliminating the formation of voids/seams in ILD layer 164), ILD layer 164 is formed by a flowable chemical vapor deposition (FCVD) process. In the depicted embodiment, the FCVD process includes depositing a flowable dielectric material 164′ over device 100 (FIG. 4A and FIG. 4B), which fills the high aspect ratio gaps/spacings S between gate structures 128; performing an ultraviolet curing 170 on deposited, flowable dielectric material 164′ (FIG. 5A and FIG. 5B); and performing an annealing process 175 on ultraviolet cured, flowable dielectric material 164′ (FIG. 6A and FIG. 6B), thereby providing ILD layer 164.

Flowable dielectric material 164′ is a flowable silicon-and-oxygen comprising dielectric material, in the depicted embodiment. Flowable dielectric materials, as their name suggest, can “flow” during deposition to fill gaps or spaces with high aspect ratios, such as gaps between gate structures 128, with negligible to no void/seam formation. In some embodiments, various chemistries, such as nitrogen-hydride bonds, are added to silicon-containing deposition precursors to allow a deposited silicon-and-oxygen comprising dielectric material to flow. For example, flowable dielectric material 164′ may be a flowable silicon-oxygen-and-nitrogen dielectric material. Exemplary flowable dielectric precursors, particularly flowable silicon oxide precursors, include silicate, siloxane, methyl-silsesquioxane (MSQ), hydrogen silsesquioxane (HSQ), perhydrosilazane (TCPS), perhydro-polysilazane (PSZ), tetraethylorthosilicate (TEOS), silyl-amine (e.g., trisilylamine (TSA)), other suitable precursor, or combinations thereof.

UV curing 170 and annealing process 175 are then performed to physically densify and/or chemically convert flowable dielectric material 164′ into ILD layer 164 (e.g., a solid dielectric material). In the depicted embodiment, UV curing 170 and/or annealing process 175 convert flowable dielectric material 164′ (e.g., a flowable silicon-oxygen-and-nitrogen comprising dielectric material) into ILD layer 164 (e.g., a silicon-and-oxygen comprising dielectric layer, such as a silicon oxide layer). In such embodiments, UV curing 170 and/or annealing process 175 may promote formation of Si—Si and/or Si—O bonds and reduce Si—N and/or Si—H bonds. In some embodiments, UV curing 170 and/or annealing process 175 may convert Si—OH, Si—H, Si—N bonds, or combinations thereof into Si—O bonds. In some embodiments, UV curing 170 and/or annealing process 175 harden flowable dielectric material 164′, thereby providing ILD layer 164. In some embodiments, UV curing 170 and/or annealing process 175 removes undesired element(s) (e.g., nitrogen) and/or bonds to densify as-deposited flowable dielectric material 164′. In some embodiments, UV curing 170 and/or annealing process 175 remove moisture and/or residuals from flowable dielectric material 164′.

Parameters of the FCVD process are configured to optimize quality of ILD layer 164 while optimizing wafer acceptance testing (WAT) performance. For example, during fabrication of device 100, native oxide may form between inner spacers 145 and sacrificial layers 115 (e.g., sacrificial semiconductor layers, such as sacrificial silicon germanium layers) (which are subsequently replaced with a gate stack) and/or between inner spacers 145 and source/drain structures 150. The present disclosure recognizes that high anneal temperatures, such as anneal temperatures greater than 500° C., may undesirably drive oxygen from the native oxide into semiconductor layers 120 (e.g., silicon layers) (which form channel layers of transistors of device 100) during the FCVD process. Such oxygen diffusion undesirably increases channel resistance (R_{ch}) and/or degrades electrical performance of transistors of device 100, such as DC performance thereof. In some instances, the channel resistance and/or electrical performance is so degraded that the transistors may fail WAT, such that wafers/chips including such transistors must be discarded. Annealing process 175 thus implements an annealing temperature that is less than about 500° C., such as about 300° C. to about 500° C., to eliminate and/or reduce such oxygen diffusion, thereby minimizing increases in channel resistance and/or degradation in electrical performance caused by such oxygen diffusion, and thereby improving WAT performance. For example, low annealing temperatures implemented by annealing process 175 may reduce oxygen diffusion length, and thus diffusion, of the oxygen, such as that into ends of semiconductor layers 120 (which may be referred to as sheet-end oxide drive-in). In some embodiments, annealing process 175 heats a wafer stage on which device 100 is secured to the annealing temperature. In some embodiments, annealing process 175 heats an ambient of a process chamber in which device 100 is disposed (e.g., surrounding environment) to the annealing temperature. In some embodiments, annealing process 175 heats flowable dielectric material 164′ to the annealing temperature, for example, to facilitate hardening/densification thereof. Annealing process 175 may heat device 100 via a wafer/substrate stage (on which substrate 105 may be secured), a lamp source, a laser source, other heat/thermal source, or combinations thereof.

Where source/drain structures 150 include germanium, the present disclosure further recognizes that an amount of source/drain oxidation, which further impacts sheet-end oxide drive-in, corresponds to an amount of germanium pile up at interfaces of source/drain structures 150 and inner spacers 145. For example, oxygen in inner spacers 145 may react with germanium in source/drain structures 150 (e.g., p-doped SiGe source/drains of p-type transistors) to form germanium oxide (e.g., GeOₓ), which may undesirably diffuse into semiconductor layers 120 during subsequent thermal processing. Low annealing temperatures implemented by annealing process 175 may also reduce germanium pile up (i.e., an amount of germanium at the inner spacer/source/drain interfaces), thereby reducing source/drain oxidation and thus reducing sheet-end oxide drive-in. For example, FIG. 11 is an exemplary plot 200 of germanium depth profiles, obtained by experimental/simulated secondary ion mass spectrometry analysis (SIMS), at interface regions of inner spacers and source/drains after forming ILD layers by FCVD processes using different annealing temperatures, according to various aspects of the present disclosure. The germanium depth profiles represent atomic percentage of germanium (Ge %) along a depth (in nm) in inner spacer/source/drain interface regions, such as from a depth/distance in a respective inner spacer (INSP) proximate an inner spacer/source/drain interface (IF) to a depth in a respective source/drain (S/D). In some embodiments, the depth represents a distance along a channel length direction from a respective inner spacer/sacrificial layer interface, through the inner spacer to a respective inner spacer/source/drain interface, and from the respective inner spacer/source/drain interface to a distance into the source/drain. In plot 200, a germanium depth profile 202 corresponds with an inner spacer/source/drain interface region after an ILD layer has been formed by an FCVD process that does not implement an annealing process, a germanium depth profile 204 corresponds with an inner spacer/source/drain interface region after an ILD layer has been formed by an FCVD process that implements a high temperature annealing process (e.g., an annealing temperature of about 500° C. to about 700° C.), and a germanium depth profile 206 corresponds with an inner spacer/source/drain interface region after an ILD layer has been formed by an FCVD process that implements a low temperature annealing process (e.g., an annealing temperature of about 300° C. to about 500° C.). As evident from plot 200, germanium atomic percentages at inner spacer/source/drain interfaces are greatest after high temperature ILD annealing and least after low temperature ILD annealing, such as that implemented by the disclosed FCVD process. The disclosed FCVD process may thus reduce germanium pile up, thereby reducing source/drain oxidation (e.g., an amount of germanium oxide at the inner spacer/source/drain interface). Reducing source/drain oxidation may further reduce unintended sheet-end oxide drive-in that may degrade transistor performance. Different embodiments may have different advantages, and no particular advantage is required of any embodiment.

The present disclosure further recognizes that the proposed lower thermal budget annealing process may undesirably degrade ILD film quality since ILD film quality is proportionally related to anneal temperature (e.g., ILD film quality may decrease as anneal temperature decreases). To compensate for ILD quality reduction that may result from the lower temperature annealing process, the disclosed FCVD process deposits a thinner layer of flowable dielectric material 164′ and exposes flowable dielectric material 164′ to higher UV power during UV curing 170, such as a power/intensity of UV radiation that is about 80% to about 100%. For example, flowable dielectric material 164′ has a thickness T1 over source/drain structures 150 (FIG. 4A), a thickness T2 over substrate isolation structures 125 (FIG. 4B), and a thickness T3 over tops of gate structures 128 (FIG. 4A). Thickness T3 is about equal to a height H3 of flowable dielectric layer 164′ over tops of gate structures 128 (i.e., thickness T3=height H3—a thickness of CESL 162 or thickness T3≈height H3). In the depicted embodiment, thickness T3 is less than about 200 nm, such as about 100 nm to about 200 nm, to facilitate improved efficiency of UV curing 170. For example, reducing thickness T3 reduces both thickness T1 (of a portion of flowable dielectric material 164′ filling the gaps between gate structures 128 in the active region) and thickness T2 (of a portion of flowable dielectric material 164′ filling the gaps between gate structures 128 in the isolation region). Reducing thickness T1 and thickness T2 reduces a distance that UV radiation/light must travel during UV curing 170, such that flowable dielectric material 164′ is exposed to UV radiation from top to bottom. In furtherance of the depicted embodiment, thickness T2 is less than about 350 nm, such as about 250 nm to about 350 nm. UV radiation, even at the proposed higher UV power/intensity, may be unable to fully penetrate thicker flowable dielectric materials, such as those having thickness T3 greater than 200 nm and/or thickness T2 greater than 350 nm, such that bottom portions of the thicker flowable dielectric materials may not be exposed to UV radiation and thus may not be UV cured.

Exposing flowable dielectric material 164′ to higher UV power, such as a UV power/intensity that is about 80% to about 100%, improves efficiency of UV curing 170, for example, by increasing exposure of flowable dielectric material 164′ to UV radiation. UV radiation having a power/intensity less than 80% may be unable to fully penetrate flowable dielectric material 164′, such that bottom portions of flowable dielectric materials may not be adequately exposed to UV radiation and thus may not be UV cured. Increasing the UV power/intensity enables shorter UV curing times, such as a curing time of about 60 seconds to about 100 seconds. In some embodiments, to improve densification and/or hardening of flowable dielectric material 164′ (and thus UV curing efficiency), UV curing 170 exposes flowable dielectric material 164′ to ozone (O₃). Exposing flowable dielectric material 164′ to ozone may incorporate additional oxygen therein. In some embodiments, UV curing 170 exposes flowable dielectric material 164′ to ozone for about 20 seconds to about 40 seconds. In some embodiments, UV curing 170 includes UV radiation pulses (e.g., where flowable dielectric material 164′ is exposed to UV radiation) and ozone pulses (e.g., where flowable dielectric material 164′ is exposed to ozone). In some embodiments, UV radiation pulses and ozone pulses may be performed separately or at least partially simultaneously. In some embodiments, a pressure maintained in a process chamber during UV curing 170 (e.g., during UV exposure and/or during ozone exposure) is about 100 Torr to about 130 Torr.

The disclosed FCVD process, which exposes the flowable dielectric material to high UV power (e.g., UV power/intensity of about 80% to about 100%) and reduces a thickness of the as-deposited flowable dielectric material (e.g., to about 100 nm to about 200 nm over tops of gate structures 128), may improve a wet etching rate of an ILD layer compared to a wet etching rate of an ILD formed by an FCVD process that exposes a flowable dielectric material having a greater as-deposited thickness (e.g., about 200 nm to about 350 nm over tops of gate structures 128) to low UV power (e.g., UV power/intensity of about 40% to about 60%). For example, FIG. 12 provides an exemplary plot 210 of a wet etch rate (WER) (in nanometers/minute (nm/min)) as a function of anneal temperature (in degree Celsius (C)) of ILD layers fabricated using different UV powers and different deposition thicknesses, according to various aspects of the present disclosure. In plot 210, a set of experimental/simulated data points is fitted with a line 212, and another set of experimental/simulated data points is fitted with a line 214. Line 212 (and its associated set of experimental/simulated data) corresponds with wet etch rates of ILD layers fabricated using UV power/intensity of about 40% to about 60% and deposition thicknesses over gate structures that are greater than 200 nm (e.g., about 200 nm to about 350 nm). Line 214 (and its associated set of experimental/simulated data) corresponds with wet etch rates of ILD layers fabricated using UV power/intensity of about 80% to about 100% and deposition thicknesses over gate structures that are less than about 200 nm (e.g., about 100 nm to about 200 nm), such as ILD layer 164 fabricated by the disclosed FCVD process. As evident from plot 210, wet etch rate decreases as anneal temperature increases, and wet etch rates of ILD layers are significantly decreased (e.g., from those corresponding with line 212 to those corresponding with line 214) by increasing UV power and decreasing deposition thickness. ILD layer 164, fabricated as described herein, thus exhibits a lower wet etch rate and improved quality. In some instances, a wet etch rate of ILD layer 164 is reduced by as much as 20% compared to wet etch rates of ILD layers fabricated by FCVD processes that implement low UV power/intensity (e.g., UV power/intensity of about 40% to about 60%) and deposition thicknesses (e.g., thickness T3/height H3) of about 200 nm to about 350 nm.

In some embodiments, the FCVD process is performed with one or more of the following process parameters to optimize high aspect ratio gap fill (i.e., minimize void/seam formation), optimize ILD film quality (e.g., reduce ILD wet etch rate), minimize sheet end oxide drive-in, minimize germanium pile up at inner spacer/source/drain interfaces, optimize WAT performance, or combinations thereof: a total as-deposited thickness of less than about 350 nm; a thickness above device features (e.g., gate structures 128) that is less than about 200 nm; a UV power/intensity of about 80% to about 100%; a UV radiation exposure time of about 60 seconds to about 100 seconds; an ozone exposure time of about 20 seconds to 40 seconds during UV curing 170; an annealing temperature of about 400° C. to about 500° C.; an annealing time of about 1 hour to about 12 hours; or combinations thereof. In some embodiments, thickness T3 of as-deposited flowable dielectric material 164′ is about 200 nm, UV curing 170 exposes flowable dielectric material 164′ to UV radiation having a power/intensity of about 90% for about 80 seconds, UV curing 170 exposes flowable dielectric material 164′ to ozone for about 20 seconds at a pressure of about 100 Torr, annealing process 175 implements an annealing temperature of about 400° C. to about 500° C. and an annealing time of about 1 hour to about 5 hours. In some embodiments, the annealing temperature is about 400° C. In some embodiments, the annealing temperature is about 450° C. In some embodiments, the annealing temperature is about 500° C. The disclosed process parameters are not randomly chosen but are specifically configured to achieve high quality ILD layers (e.g., those with reduced wet etch rates) while optimizing electrical performance (and thus improving WAT metrics). For example, if the as-deposited thickness is too thick (e.g., greater than 200 nm over tops of gate structures 128), the UV power is too low (e.g., less than 80%), and the annealing temperature is too low (e.g., less than about 300° C.), then flowable dielectric material 164′ may not be adequately cured/annealed, such that ILD layer 164 may exhibit poor quality, such a higher than desirable etch rate that may cause ILD layer 164 to suffer undercutting and/or other adverse effects when etching ILD layer 164 during source/drain contact formation. On the other hand, if the annealing temperature is too high (e.g., greater than about 500° C.), then sheet end oxide-drive in and/or germanium pile up may be alter performance of device 100, sometimes to the point of device failure/discard. The specifically configured process parameter ranges are thus provided to optimize ILD quality and WAT performance, which can improve overall performance of device 100 without negatively impacting fabrication throughput and/or fabrication complexity.

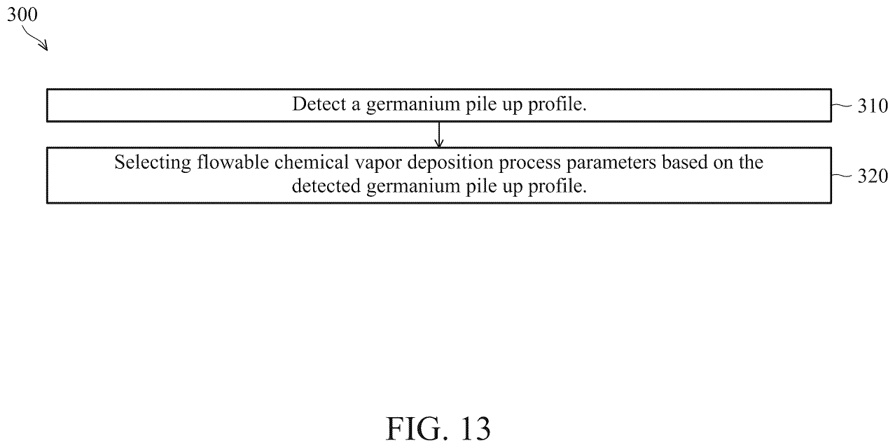

Because the present disclosure recognizes that an amount of source/drain oxidation corresponds to an amount of germanium pile up, the present disclosure further proposes monitoring and/or predicting source/drain oxidation by evaluating/monitoring germanium pile up profile(s). For example, FIG. 13 is a flow chart of a method 300, in portion or entirety, for improving quality of FCVD layers and/or electrical performance of devices that include such layers based on germanium pile up profiles, according to various aspects of the present disclosure. may be implemented by method 10. Method 300 includes detecting a germanium pile up profile at block 310 and selecting FCVD process parameters based on the detected germanium pile up profile at block 320. For example, if the detected germanium pile up profile is above a pile up threshold (which corresponds with detrimental amounts of source/drain oxidation that may lead to levels of sheet end oxide drive-in that degrade device performance to an extent that its corresponding device (e.g., transistor) may fail WAT), a high power, low temperature FCVD process (e.g., UV power of about 80% to about 100% and anneal temperature of about 400° C. to about 500° C.) may be implemented to form an ILD layer over a source/drain, such as described above and herein. If the detected germanium pile up profile is below a pile up threshold (which corresponds with negligible source/drain oxidation or an acceptable amount of source/drain oxidation (i.e., an amount that does not negatively and/or significantly impact device performance, such that the semiconductor device may pass WAT), a low power, high temperature FCVD process (e.g., UV power of about 40% to about 60% and anneal temperature of about 500° C. to about 700° C.) may be implemented to form the ILD layer. The low power, high temperature FCVD process may be configured to deposit a thicker ILD layer, such as an ILD layer having a total thickness that is greater than about 300 nm and an upper thickness that is greater than about 200 nm, while the high power, low temperature FCVD process may be configured to deposit a thinner ILD layer, such as an ILD layer having a total thickness that is less than about 300 nm and an upper thickness that is less than about 200 nm. In some embodiments, the detected germanium pile up profile is based on measured and/or simulated characteristics of a device over which the ILD layer is fabricated and/or devices over which ILD layers have been fabricated. The germanium pile up profile may be a SIMS profile, which may be a simulated SIMS profile or an actual SIMS profile. In some embodiments, the FCVD process parameters may be selected based on germanium pile up profiles of source/drains across an entire wafer or a portion thereof, where the FCVD process forms an ILD layer over the source/drains of the wafer. In some embodiments, method 10 implements method 300 at block 20 to tune FCVD process parameters and achieve desired ILD quality. Additional steps may be provided before, during, and after method 300, and some of the steps described may be moved, replaced, or eliminated for additional embodiments of method 300.

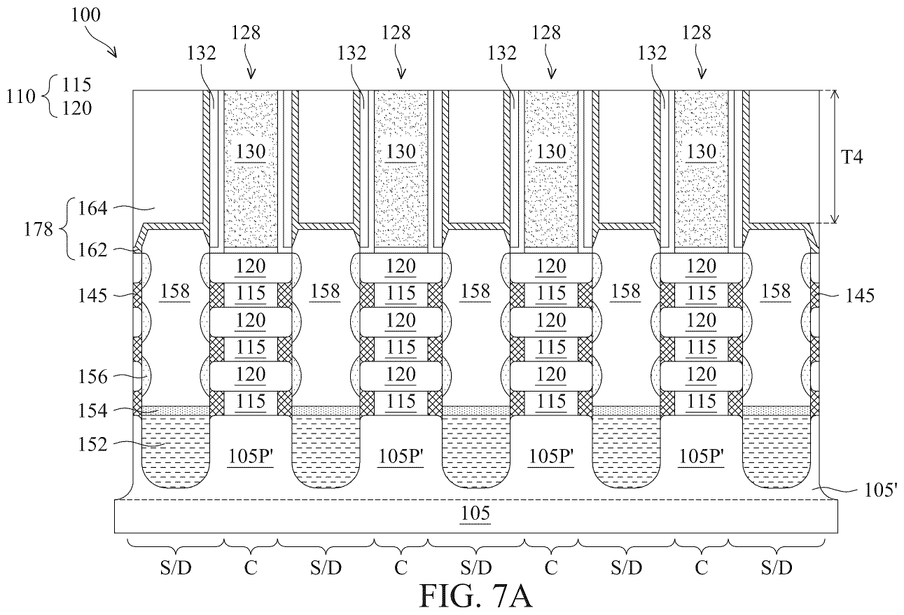

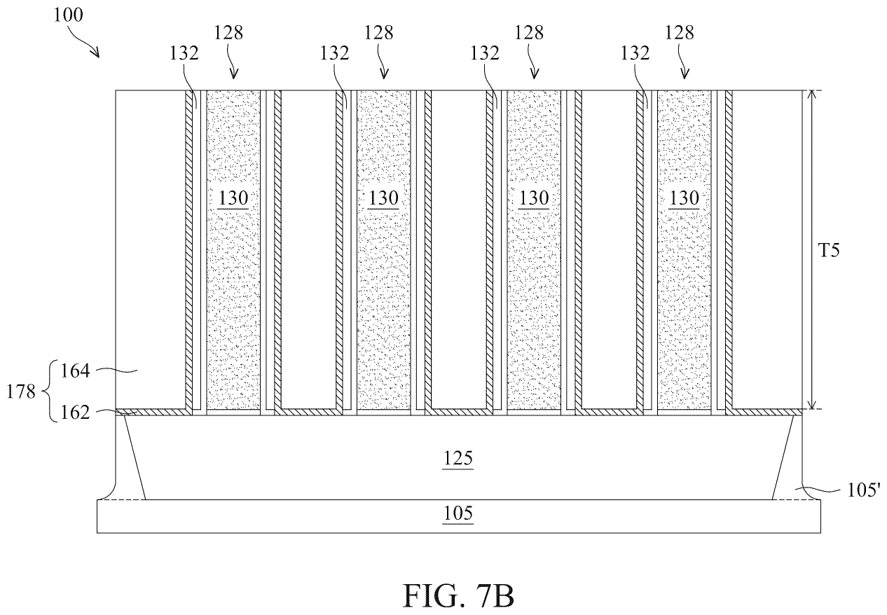

Referring to FIG. 7A and FIG. 7B, a planarization process (e.g., a chemical mechanical polishing (CMP) process) is performed on ILD layer 164 and CESL 162. The planarization process is performed until reaching and exposing gate structures 128, such as dummy gate stacks 130 thereof. The planarization process may remove portions of ILD layer 164 and portions of CESL 162 that extend above and/or are disposed over tops of gate structures 128. Remainders of ILD layer 164 and CESL 162 form a device-level dielectric layer 178 over source/drain structures 150 and substrate isolation structures 125. Device-level dielectric layer 178 may fill gaps/spaces between the adjacent gate structures 128 (e.g., between gate spacers 132 thereof) and/or gaps/spaces between adjacent source/drain structures 150 (e.g., along the y-direction and/or in the Y-Z plane). In some embodiments, dummy gate stacks 130 (e.g., hard masks thereof) and/or gate spacers 132 function as a planarization stop layer (e.g., a CMP stop layer). In some embodiments, the planarization process is performed for a time sufficient to expose dummy gate stacks 130. The planarization process may planarize a top surface of device-level dielectric layer 178 (which may be formed by ILD layer 164 and CESL 162), top surfaces of dummy gate stacks 130, and top surfaces of gate spacers 132. The planarized top surfaces may form a substantially planar surface of device 100 after the planarization process.

The planarization process reduces a thickness of ILD layer 164. For example, the planarization process reduces a thickness of ILD layer 164 over source/drain structures 150 from thickness T1 to thickness T4, a thickness of ILD layer 164 over substrate isolation structures 125 from thickness T2 to thickness T5, and a thickness of ILD layer 164 over gate structures 128 from thickness T3 to zero. In some embodiments, the planarization process removes about 100 nm to about 200 nm of ILD layer 164.

Referring to FIGS. 8A-8C, in some embodiments, a gate replacement process may be performed to replace dummy gate stacks 130 with gate stacks 180. In some embodiments, dummy gate stacks 130 are removed to form gate openings (e.g., between gate spacers 132) that expose multilayer stack 110, such as semiconductor layers 120 and sacrificial layers 115 thereof, in the channel regions of active region 160. For example, an etching process selectively removes dummy gate stacks 130 with negligible (to no) removal of device-level dielectric layer 178, gate spacers 132, inner spacers 145, sacrificial layers 115, semiconductor layers 120, or combinations thereof. The etching process is a dry etch, a wet etch, other suitable etch, or combinations thereof. In some embodiments, the etching process may use a patterned mask layer as an etch mask, and the patterned mask layer may cover device-level dielectric layer 178 and/or gate spacers 132 and have openings therein that expose dummy gate stacks 130.

During the gate replacement process, before forming gate stacks 180, a channel release process may be performed to form suspended channel layers. For example, sacrificial layers 115 exposed by the gate openings are selectively removed to form gaps between semiconductor layers 120 and gaps between semiconductor layers 120 and mesas 105P′, thereby suspending semiconductor layers 120 in the channel regions. In the depicted embodiment, each channel region has three suspended semiconductor layers 120, which are referred to hereafter as channel layers 120′, vertically stacked along the z-direction for providing three channels through which current can flow between respective source/drain structures 150 during operation of transistors of device 100. In some embodiments, an etching process selectively etches sacrificial layers 115 with minimal (to no) etching of semiconductor layers 120, mesas 105P′, gate spacers 132, inner spacers 145, device-level dielectric layer 178, or combinations thereof. In some embodiments, an etchant is selected for the etch process that etches silicon germanium (e.g., sacrificial layers 115) at a higher rate than silicon (e.g., semiconductor layers 120, mesas 105P′, etc.) and dielectric materials (e.g., gate spacers 132, inner spacers 145, device-level dielectric layer 178, etc.). In some embodiments, an etchant is selected for the etching process that etches a dielectric material having a first composition (e.g., sacrificial layers 115) at a higher rate than silicon (e.g., semiconductor layers 120, mesas 105P′, etc.) and dielectric materials having compositions different than the first composition (e.g., gate spacers 132, inner spacers 145, device-level dielectric layer 178, etc.). The etching process is a dry etch, a wet etch, other suitable etch, or combinations thereof. In some embodiments, before the etching process, an oxidation process may convert sacrificial layers 115 into silicon germanium oxide layers, and the etching process may then remove the silicon germanium oxide layers. In some embodiments, an etching process is performed to modify a profile of semiconductor layers 120/channel layers 120′ to achieve target channel dimensions and/or target channel shapes.

Gate stacks 180 (also referred to as high-k/metal gates) may then be formed in the gate openings and/or the gaps. Gate stacks 180 have portions disposed between respective gate spacers 132 and portions disposed between respective inner spacers 145. Gate stacks 180 are further disposed between channel layers 120′ and between channel layers 120′ and mesas 105P′. In the depicted embodiment, where device 100 includes GAA transistors, gate stacks 180 may surround and engage respective channel layers 120′, for example, in the Y-Z plane (see, e.g., FIG. 8C). In some embodiments, gate stacks 180 may wrap and/or partially surround respective channel layers 120′ (i.e., be disposed on at least two sides thereof).

Each gate stack 180 may include a gate dielectric 182. Gate dielectrics 182 are disposed on channel layers 120′, mesas 105P′, inner spacers 145, gate spacers 132, or combinations thereof. Gate dielectrics 182 may have the same or different compositions and/or configurations. Gate dielectrics 182 include at least one dielectric layer, such as an interfacial layer and/or a high-k dielectric layer. The interfacial layer includes a dielectric material, such as SiO₂, SiGeOₓ, HfSiO, SiON, other dielectric material, or combinations thereof. The high-k dielectric layer includes a high-k dielectric material, which generally refers to dielectric materials having a dielectric constant greater than a dielectric constant of silicon dioxide, such as HfO₂, HfSiO, HfSiO₄, HfSiON, HfLaO, HfTaO, HfTIO, HfZrO, HfAlOx, ZrO, ZrO₂, ZrSiO₂, AlO, AlSiO, Al₂O₃, TIO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr) TiO₃ (BST), HfO₂—Al₂O₃, other high-k dielectric material, or combinations thereof. In some embodiments, each gate dielectric 182 may include a hafnium-based oxide (e.g., HfO₂) layer and/or a zirconium-based oxide (e.g., ZrO₂) layer.

Each gate stack 180 may include a gate electrode 184. Gate electrodes 184 are disposed over gate dielectrics 182. Gate electrodes 184 may have the same or different compositions and/or configurations, and gate electrodes 184 include at least one electrically conductive layer formed of an electrically conductive material, which may include Al, Cu, Ti, Ta, W, Mo, Co, TaN, NiSi, CoSi, TiN, WN, TiAl, TiAlN, TaCN, TaC, TaSiN, other electrically conductive constituent, or combinations thereof. In some embodiments, gate electrodes 184 include a work function layer. The work function layer is a conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TIC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, gate electrodes 184 include a bulk layer over gate dielectric 182 and/or the work function layer. The bulk layer may include Al, W, Cu, Ti, Ta, TiN, TaN, polysilicon, other suitable metal(s) and/or alloys thereof, or combinations thereof. In some embodiments, gate electrodes 184 include a barrier layer over the work function layer and/or gate dielectric 182. The barrier layer includes a material that may prevent diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Forming gate stacks 180 may include depositing gate dielectric material (e.g., interfacial layers, high-k dielectric layers, etc.) that partially fill the gate openings, depositing gate electrode material (e.g., work function layers, barrier layers, bulk layers, etc.) that fill remainders of the gate openings, and performing a planarization process to remove portions of the gate dielectric material and/or portions of the gate electrode material over device-level dielectric layer 178. In some embodiments, fabrication of device 100 may further include etching back gate stacks 180 and forming hard masks (e.g., self-aligned cap (SAC) structures) over the etched-back gate stacks 180. The SAC structures include a material that is different than ILD layer 164 and/or subsequently formed dielectric layers to achieve etch selectivity. In some embodiments, the SAC structures include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, the SAC structures include metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or combinations thereof. Though the depicted embodiment fabricates gate stacks 180 according to a gate last process, the present disclosure contemplates embodiments where the metal gate stacks of device 100 may be fabricated according to a gate first process or a hybrid gate last/gate first process.

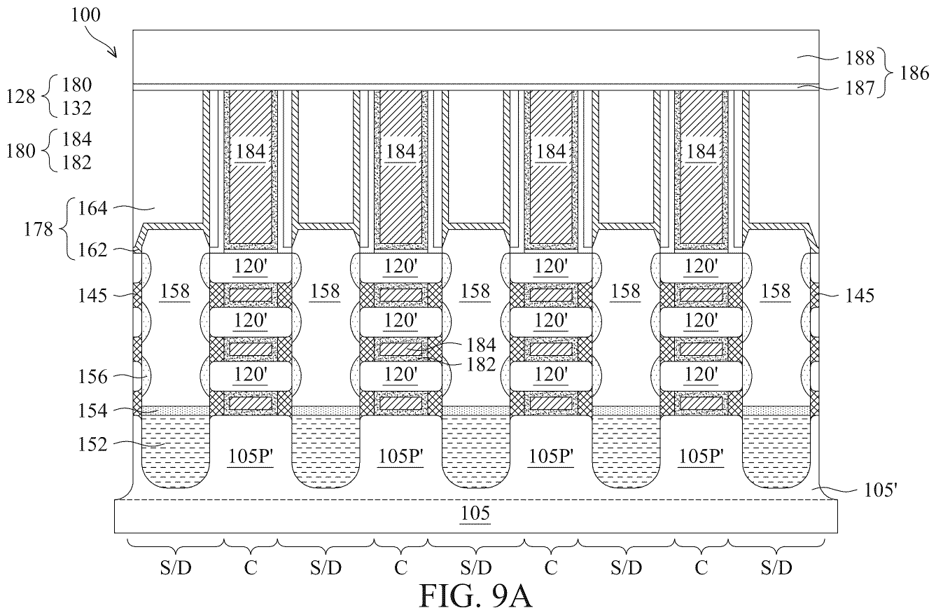

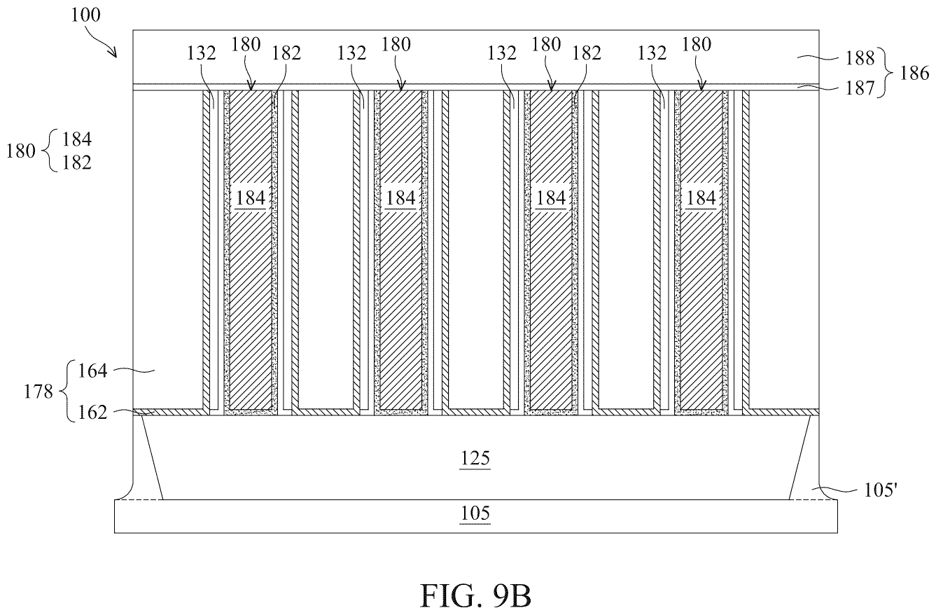

Referring to FIG. 9A and FIG. 9B, a dielectric layer 186 may be formed over device-level dielectric layer 178. In some embodiments, dielectric layer 186 includes a contact etch stop layer (CESL) 187 and an ILD layer 188. CESL 187 is formed on ILD layer 164 and gate structures 128, and ILD layer 188 is formed on CESL 187. In some embodiments, forming dielectric layer 186 includes depositing CESL 187 over device-level dielectric layer 178, depositing an ILD layer 188 over CESL 187, and performing a CMP and/or other planarization process on ILD layer 188. Because device 100 may be free of gaps between device features after forming device-level ILD layer 178 and/or include smaller aspect ratio gaps than the aspect ratios of the gaps between gate structures 128, a different type of CVD process may be implemented to form ILD layer 188. For example, the aspect ratio may be zero, and ILD layer 188 may be formed by plasma enhanced CVD (PECVD), instead of FCVD.

ILD layer 188 may be configured similar to ILD layer 164. For example, ILD layer 188 includes a dielectric material, including, for example, silicon oxide, carbon doped silicon oxide, TEOS-formed oxide, PSG, BSG, BPSG, FSG, xerogel, aerogel, amorphous fluorinated carbon, parylene, BCB-based dielectric material, polyimide, other suitable dielectric material, or combinations thereof. The dielectric material may be a same dielectric material as or a different dielectric material than that of ILD layer 164. In some embodiments, ILD layer 188 is a low-k dielectric layer, such as a silicon-and-oxygen comprising dielectric layer having a dielectric constant less than about 3.9, and in some embodiments, less than about 2.5.

CESL 187 may be configured and/or formed similar to CESL 162. CESL 187 includes a material different than ILD layer 188 to enable etching selectivity therebetween, such as a dielectric material that is different than the dielectric material of ILD layer 188. In some embodiments, CESL 187 includes silicon and nitrogen. For example, CESL 187 is a silicon nitride layer and/or a silicon oxynitride layer. ILD layer 188 and/or CESL 187 may have a multilayer structure and/or include multiple dielectric materials, in some embodiments.

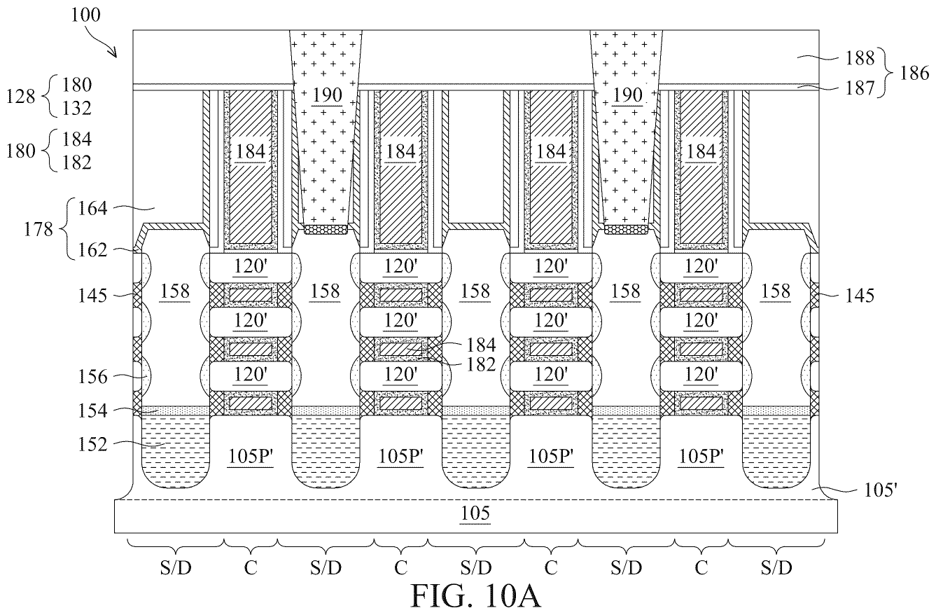

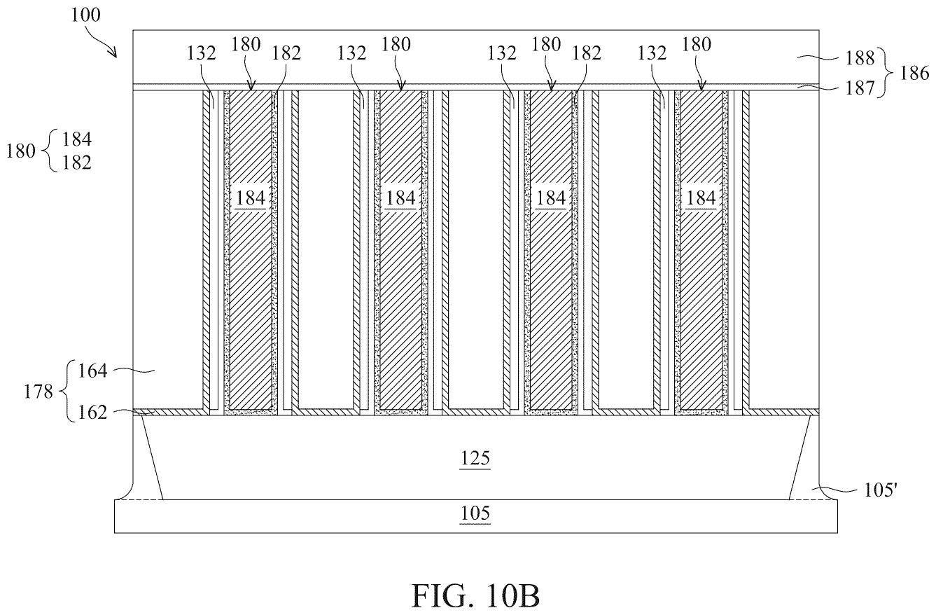

Referring to FIG. 10A and FIG. 10B, in some embodiments, at least one source/drain contact 190 is formed to a respective source/drain structure 150. In the depicted embodiment, source/drain contacts 190 are formed in device-level dielectric layer 178 (e.g., ILD layer 164 and CESL 162) and dielectric layer 186 (e.g., ILD layer 188 and CESL 187). In some embodiments, forming source/drain contacts 190 includes forming source/drain contact openings (e.g., by an etching process) that extend through dielectric layer 186 and device-level dielectric layer 178 to expose respective source/drain structures 150, depositing at least one electrically conductive material (e.g., a metal bulk material) over dielectric layer 86 that fills the source/drain contact openings, and performing a planarization process to remove any of the electrically conductive material that is disposed over a top of dielectric layer 186. The planarization process may be performed until reaching and exposing ILD layer 188. Remainders of the electrically conductive material form metal plugs and, in some embodiments, one or more liners of source/drain contacts 190. The electrically conductive material includes tungsten, ruthenium, cobalt, molybdenum, copper, aluminum, titanium, tantalum, iridium, palladium, platinum, nickel, tin, gold, silver, other suitable metal, alloys thereof, or combinations thereof. Because ILD layer 164 is fabricated as described herein, source/drain contact openings may exhibit improved profiles that increase the likelihood of device 100 passing WAT. For example, when formed by other FCVD processes, ILD layer 164 may exhibit significant undercutting, which may result in cavities in ILD layer 164 that are undesirably filled with the electrically conductive material, thereby undesirably reducing a distance between source/drain contacts 190 and electrically conductive device features, such as gate structures 128 (e.g., gate stacks 180 thereof), which may lead to electrical shorting therebetween that results in device 100 being deemed defective. In contrast, because ILD layer 164 is fabricated as described herein (and thus exhibits a lower etch rate), ILD layer 164 may be free of and/or exhibit negligible undercutting after forming source/drain contact openings, such that ILD layer 164 is free of cavities therein that would laterally extend source/drain contacts too far. In some embodiments, silicide layers are formed over exposed doped semiconductor layers 158 before depositing the electrically conductive material.

The present disclosure provides for many different embodiments. An exemplary flowable chemical vapor deposition method includes depositing a flowable dielectric material over a substrate. The flowable dielectric material fills a space between a first gate structure and a second gate structure. The flowable chemical vapor deposition method further includes ultraviolet curing the flowable dielectric material and annealing the ultraviolet cured, flowable dielectric material. An ultraviolet power of the ultraviolet curing is greater than about 80%, and an annealing temperature of the annealing is less than about 500° C.

In some embodiments, the annealing temperature is about 400° C. to about 500° C. and an annealing time of the annealing is about 1 hour to about 5 hours. In some embodiments, the ultraviolet curing includes exposing the flowable dielectric material to ozone (O₃). In some embodiments, the power of the ultraviolet curing is about 80% to about 100% and a curing time of the ultraviolet curing is about 60 seconds to 100 seconds. In some embodiments, the ultraviolet power is 90% and the annealing temperature is 400° C. In some embodiments, the ultraviolet power is 90% and the annealing temperature is 450° C. In some embodiments, the ultraviolet power is 90% and the annealing temperature is 500° C.

In some embodiments, a thickness of the flowable dielectric material deposited over tops of the first gate structure and the second gate structure is less than about 200 nm. In some embodiments, the flowable chemical vapor deposition method further includes selecting the thickness of the flowable dielectric material deposited over tops of the first gate structure and the second gate structure based on germanium pile up characteristics expected at an inner spacer/source/drain interface. In some embodiments, the flowable chemical vapor deposition method further includes selecting the ultraviolet power and the annealing temperature based on germanium pile up characteristics expected at an inner spacer/source/drain interface.

An exemplary method includes performing a flowable chemical vapor deposition (FCVD) process to form a first interlayer dielectric (ILD) layer over a substrate and performing a CVD process to form a second ILD layer over the first ILD layer. In some embodiments, the first ILD layer fills gaps between gate structures, the FCVD process implements an ultraviolet power of about 80% to about 100%, and the FCVD process implements a temperature of about 300° C. to about 500° C. In some embodiments, an as-deposited thickness of the first ILD layer over tops of the first gate structure and the second gate structure is less than about 200 nm and the method further includes performing a planarization process on the first ILD layer. In some embodiments, the method further includes forming a source/drain contact in the second ILD layer and the first ILD layer. The source/drain contact may be disposed between a first one of the gate structures and a second one of the gate structures.

In some embodiments, performing the CVD process includes performing a plasma-enhanced CVD (PECVD) process. In some embodiments, the FCVD process includes a deposition process, a curing process that implements the ultraviolet power, and a thermal process that implements the temperature, and a duration of the curing process is less than a duration of the thermal process. In some embodiments, the gaps between the gate structures have a first aspect ratio in an isolation region and a second aspect ratio in an active region, and the first aspect ratio is greater than the second aspect ratio. In some embodiments, the first aspect ratio is greater than 10. In some embodiments, the method further includes selecting the ultraviolet power, the temperature, and an as-deposited thickness of the first ILD layer based on a sheet end oxide drive-in model. The sheet end oxide drive-in model may be generated based on germanium pile up characteristics expected at an inner spacer/source/drain interface.

Another exemplary method includes analyzing germanium pile up profile characteristics corresponding with interface regions of inner spacers and source/drain structures of a set of devices having device-level interlayer dielectric layers. Each of the device-level interlayer dielectric layers has a corresponding set of flowable chemical vapor deposition process parameters. The method further includes selecting flowable chemical vapor deposition process parameters for a device-level interlayer dielectric layer to be formed by a flowable chemical vapor deposition process based on the analyzed germanium pile up profile characteristics. In some embodiments, the method further includes forming the given device-level interlayer dielectric layer using the selected flowable chemical vapor deposition process parameters. The given device-level dielectric layer may be formed over source/drain structures, and the device-level dielectric layer may fill gaps between gate structures. In some embodiments, the flowable chemical vapor deposition process parameters include an ultraviolet power of an ultraviolet curing process, an annealing temperature of an annealing process, and an as-deposited thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a flowable dielectric material over a substrate, wherein the flowable dielectric material fills a space between a first gate structure and a second gate structure;
ultraviolet curing the flowable dielectric material, wherein an ultraviolet power of the ultraviolet curing is greater than about 80%; and
annealing the ultraviolet cured, flowable dielectric material, wherein an annealing temperature of the annealing is less than about 500° C.

2. The method of claim 1, wherein a thickness of the flowable dielectric material deposited over tops of the first gate structure and the second gate structure is less than about 200 nm.

3. The method of claim 2, further comprising selecting the thickness of the flowable dielectric material deposited over tops of the first gate structure and the second gate structure based on germanium pile up characteristics expected at an inner spacer/source/drain interface.

4. The method of claim 1, further comprising selecting the ultraviolet power and the annealing temperature based on germanium pile up characteristics expected at an inner spacer/source/drain interface.

5. The method of claim 1, wherein:
the annealing temperature is about 400° C. to about 500° C.; and
an annealing time of the annealing is about 1 hour to about 5 hours.

6. The method of claim 1, wherein the ultraviolet curing includes exposing the flowable dielectric material to ozone (O₃).

7. The method of claim 1, wherein:
the ultraviolet power of the ultraviolet curing is about 80% to about 100%; and
a curing time of the ultraviolet curing is about 60 seconds to 100 seconds.

8. The method of claim 1, wherein the ultraviolet power is 90% and the annealing temperature is 400° C.

9. The method of claim 1, wherein the ultraviolet power is 90% and the annealing temperature is 450° C.

10. The method of claim 1, wherein the ultraviolet power is 90% and the annealing temperature is 500° C.

11. A method comprising:
performing a flowable chemical vapor deposition (FCVD) process to form a first interlayer dielectric (ILD) layer over a substrate, wherein the first ILD layer fills gaps between gate structures, the FCVD process implements an ultraviolet power of about 80% to about 100%, and the FCVD process implements a temperature of about 300° C. to about 500° C.; and
performing a CVD process to form a second ILD layer over the first ILD layer.

12. The method of claim 11, wherein the performing the CVD process includes performing a plasma-enhanced CVD (PECVD) process.

13. The method of claim 11, wherein:
the FCVD process includes a deposition process, a curing process that implements the ultraviolet power, and a thermal process that implements the temperature; and
a duration of the curing process is less than a duration of the thermal process.

14. The method of claim 11, wherein the gaps between the gate structures have a first aspect ratio in an isolation region and a second aspect ratio in an active region, the first aspect ratio is greater than the second aspect ratio, and the first aspect ratio is greater than 10.

15. The method of claim 11, further comprising selecting the ultraviolet power, the temperature, and an as-deposited thickness of the first ILD layer based on a sheet end oxide drive-in model, wherein the sheet end oxide drive-in model is generated based on germanium pile up characteristics expected at an inner spacer/source/drain interface.

16. The method of claim 11, wherein an as-deposited thickness of the first ILD layer over tops of the gate structures is less than about 200 nm and the method further includes performing a planarization process on the first ILD layer.

17. The method of claim 11, further comprising forming a source/drain contact in the second ILD layer and the first ILD layer, wherein the source/drain contact is disposed between a first one of the gate structures and a second one of the gate structures.

18. A method comprising:
analyzing germanium pile up profile characteristics corresponding with interface regions of inner spacers and source/drain structures of a set of devices having device-level interlayer dielectric layers, wherein each of the device-level interlayer dielectric layers has a corresponding set of flowable chemical vapor deposition process parameters; and
selecting flowable chemical vapor deposition process parameters for a respective device-level interlayer dielectric layer to be formed by a flowable chemical vapor deposition process based on the analyzed germanium pile up profile characteristics.

19. The method of claim 18, further comprising forming the respective device-level interlayer dielectric layer using the selected flowable chemical vapor deposition process parameters, wherein the respective device-level interlayer dielectric layer is formed over source/drain structures and the respective device-level interlayer dielectric layer fills gaps between gate structures.

20. The method of claim 18, wherein the flowable chemical vapor deposition process parameters include an ultraviolet power of an ultraviolet curing process, an annealing temperature of an annealing process, and an as-deposited thickness.
